(19) United States
(12) Patent Application Publication
(10) Pub. No.: US 2015/0301087 A1
(43) Pub. Date: Oct. 22, 2015

(54) Differential current measuring module

(71) Applicant: Bender GmbH & Co. KG, Gruenberg (DE)

(72) Inventors: Winfried Moell, Laubach (DE); Michael Kammer, Hungen (DE); Michael Prinz-Weinel, Ranstadt (DE)

(21) Appl. No.: 14/688,048

(22) Filed: Apr. 16, 2015

(30) Foreign Application Priority Data
Apr. 16, 2014 (DE) 10 2014 005 538.8

(51) Int. Cl. G01R 15/18; G01R 17/00; G01R 15/22

(52) U.S. Cl. CPC G01R 15/18; G01R 15/22; G01R 17/00

(57) ABSTRACT

A differential current measuring module is composed of a housing that encases a current transformer core and a printed circuit board, the current transformer core surrounding a line duct of the housing and having at least one secondary winding. The differential current measuring module is characterized in that in the line duct, at least one primary conductor is led out on a top side of the housing to be connected to an external electrical feed line and whose other end protrudes out of a bottom side of the housing and is provided with a solder terminal. The principle idea is based on continuing the electrical line to be monitored, in sections, as a primary conductor in the effective area of the current transformer core so as to advantageously arrive at a differential current measuring device whose integration is constructionally simple and which offers an uncomplicated connecting option.

This application claims the benefit of German Patent Application No. 10 2014 005 538.8, filed Apr. 16, 2014, the disclosure of which is incorporated herein by reference.

### FIELD OF THE INVENTION

The invention relates to a differential current measuring module composed of a housing that encases a current transformer core and a printed circuit board, the current transformer core surrounding a line duct of the housing and having at least one secondary winding.

### BACKGROUND

Measuring devices such as residual current monitoring devices (RCMs) or residual current protection devices (RCDs) are sufficiently known for the purpose of monitoring and protection of electrical installations.

Said known methods and devices are predominantly based on the principle of galvanically isolated differential current measurement in which all active conductors of an electrical line to be monitored are led as a primary winding (primary conductor) through a measuring current transformer having an annular current transformer core made of a ferromagnetic material and having at least one secondary winding. The current transformer core is usually incorporated in a housing that has a line duct for the feed line to be monitored, wherein the current transformer core annularly surrounds the line duct.

Measuring devices of this kind are also used for arc detection in electrical installations and increasingly for monitoring and protecting charging devices for charging energy accumulators in electric vehicles. For instance, standard IEC 62752 specifies that the charging process in an IC-CPD (In-Cable Control and Protection Device) has to be monitored by means of a differential current sensor system for single-phase and three-phase charging devices. The differential current measuring device must be capable of processing different amperages, such as 3×32 A or 2×80 A, depending on the charging mode. Furthermore, there are additional requirements regarding the detection of a direct residual current.

To comply with the normative requirements, RCMs known from the state of the art have been used so far, which measure the differential current, if needed, in an AC/DC-sensitive manner. In charging devices for electric vehicles, type B RCDs or special RCDs with 6 mA monitoring can be used.

The use of known differential current measuring devices proves disadvantageous because of their constructionally elaborate integration into electrical installations, for example into a charging device having an integrated control and protection device, because the primary conductors have to be led through the current transformer in oftentimes restricted installation spaces and have to be wired by hand in an elaborate and expensive fashion on a printed mounting board.

### SUMMARY

Therefore, it is the object of the present invention to create a differential current measuring device that can be integrated into electrical installations in a constructionally simple and thus cost-effective manner.

Said object is attained in conjunction with the preamble of claim 1 in that at least one primary conductor is arranged in the line duct that is led out on a top side of the housing so as to be connected to an external electrical feed line and whose other end protrudes out of a bottom side of the housing and is provided with a solder terminal.

The principle idea of the present invention is based on continuing the electrical line to be monitored, in sections, as a primary conductor in the effective area of the current transformer core in such a manner that a constructionally simple integration of a differential current measuring device including an uncomplicated connecting option is possible in an advantageous fashion.

The primary conductor led out at the top side of the housing allows an electrical connection to the feed line to be monitored so that it is unnecessary to lead said feed line through the current transformer core. In particular in case of little available installation space, the installation and integration of a differential current measuring device is significantly facilitated.

Without any elaborate assembly work and without any further wiring effort, it is only necessary to connect the feed line to be monitored to the primary conductor led out at the top side of the housing.

At its opposite end, the primary conductor protrudes beyond the bottom side of the housing and is provided with a solder terminal. When mounting the differential current measuring module on a printed mounting board, said solder terminal can be connected to solder contacts (solder pads) on the printed mounting board, ensuring in a simple fashion an electrical connection of the feed line to be monitored to a subsequent electrical circuit. No additional wiring is required on the printed mounting board.

Owing to its compact architecture, the differential current measuring module according to the invention is suited in particular for the use in operating environments with restricted installation space, such as in charging stations and charging cables for electric vehicles for detecting residual currents. The use as single-phase or multi-phase differential current sensor system for photovoltaic inverters, integrated into an AC-inverter connection contact strip or in frequency inverters for regulating electric drives is advantageous as well.

In another advantageous embodiment, a separating web running parallel to the line duct is arranged in the line duct for keeping the distances of the primary conductor.

The separating web separates the single primary conductor, causing a reduction of the clearances and creepage distances. Owing to the separating web, compliance with the insulation requirements can be ensured at minimal distance of the primary conductor to other electrically conductive components or to adjacent primary conductors. Moreover, the separating web allows the use of a primary conductor without its own insulation or encapsulation.

Furthermore, the separating web arranged in the line duct is composed of four web walls that are arranged in the shape of a cross so that the line duct is divided into four separate conductor channels, in each of which a primary conductor is led in an isolated manner.

In connection with an electrical feed line that comprises four active conductors (phase conductors L1, L2, L3 and neutral conductor N), said active conductors can be led in a mutually isolated manner in separate conductor channels owing to the four web walls of the cruciform separating web.

The separating web advantageously protrudes beyond the top side of the housing so that the primary conductor can be continued in an isolated manner in the outward direction above the housing.

The prolongation of the separating web beyond the top side of the housing also ensures the separation of the primary conductor if the primary conductor is continued outside of the housing. In particular in case of a multi-phase feed line with four active conductors, the cruciform separating web protruding out of the top side of the housing allows a continuation of the primary conductor that is cruciform, directed outward and thus safe within the meaning of the insulation requirements.

Furthermore, the separating web protrudes beyond the bottom side of the housing.

When mounting the differential current module on a printed mounting board, the separating web protruding beyond the bottom side of the housing can enter a slot of the printed mounting board. Thus, it is also ensured that sufficient distances of the primary conductors are kept when they exit at the bottom side of the housing.

In another embodiment, the separating web is realized as a separate component that can be inserted into and removed from the line duct of the housing.

The realization of the separating web as a separate component allows flexibly using the differential current measuring module with or without a separating web. For example, it is unnecessary to insert a separating web if primary conductors are used that are sufficiently insulated on their own.

Advantageously, clamping devices for securing the primary conductor that is led out of the line duct in a rectangular fashion are attached to the top side of the housing.

The clamping devices can be realized as snap-lock elements, for example, and they cause a fixation of the primary conductor(s) that is/are led out in an almost rectangular fashion at the top side of the housing. In case of the multi-phase feed line with four active conductors being led out, said active conductors are secured to the surface of the housing in cruciform arrangement by means of the clamping devices.

Furthermore, the line duct of the housing has a conical expansion at the bottom side of the housing so that the primary conductors can be positioned at larger distances while being bent radially to the outside.

The conical expansion of the line duct at the bottom side of the housing allows the primary conductors to be installed so as to be bent radially outward. Thus, the distances between the solder terminals on the printed mounting board are larger and the clearances and creepage distances are advantageously longer.

The housing has an upper housing part and a lower housing part, which can be connected to each other by means of a latching connection. In an alternative embodiment, the housing can be a housing that is cast in one piece.

In a preferred embodiment, the current transformer core is mounted on supporting pads for internal positioning in the housing.

By positioning the current transformer core on supporting pads, installation space is available below the current transformer core between the housing bottom and the current transformer core for arranging the printed circuit board with the electronic components arranged thereon.

In an advantageous embodiment, output signals that are generated by an evaluating circuit arranged on the printed circuit board are led out at the bottom side of the housing via pin contacts.

The evaluating circuit arranged on the printed circuit board is an integral component of the differential current module. For processing of the output signals generated in the evaluating circuit, said output signals are led out via pin contacts embedded into the housing bottom and are transmitted to a printed mounting board, for example, onto which the differential current measuring module is mounted. The printed circuit board carrying the evaluating circuit can also be realized as a flexible printed circuit board (FPC—flexible printed circuit) and be formed around the current transformer core in a place-saving manner. The evaluating electronics can also be mounted within a shielded transformer housing surrounding the current transformer core.

Preferably, the primary conductor is provided with a plug contact at the end led out at the top side of the housing.

The plug contacting allows quick production of a detachable electrical connection to the feed line to be monitored without the aid of further connecting elements.

In another preferred embodiment, the primary conductor provided with the plug contact is realized as a separate constructional unit that can be inserted into and removed from the line duct of the housing.

In said embodiment, the differential current measuring module is composed of the housing into whose line duct the primary conductors provided with the plug contact can be inserted as a separate constructional unit. If a separating web is additionally present, said separating web can also be part of the separate constructional unit.

Thus, it is possible to also operate the differential current measuring module without the use of a plug contact of the primary conductor by using a feed line that is led through the line duct as a primary conductor, for example.

Furthermore, the differential current measuring module has a plug housing through which the plug contacts of the primary conductor protrude and can be contacted with a mating plug.

The housing itself can be realized as a plug housing or be enclosed by an additional plug housing, wherein the plug contacts of the primary conductors produce the electrical contacting to the outside.

### BRIEF DESCRIPTION OF THE DRAWING FIGURES

Further advantageous embodiment features become apparent from the following description and from the drawings, which illustrate a preferred embodiment of the invention by way of examples. In the figures:

FIG. 1: shows an external view of a differential current measuring module according to the invention,

FIG. 2: shows an internal structure of the differential current measuring module,

FIG. 3: shows a detailed view of the supporting pads,

FIG. 4: shows a version of the differential current measuring module having a cylindrical line duct and a constant diameter,

FIG. 5: shows a version of the differential current measuring module having a cylindrical line duct and a conical expansion,

FIG. 6: shows a printed mounting plate having a slot for a cruciform separating web and having solder pads, and

FIG. 7: shows the differential current measuring module having plug contacts at the primary conductor ends.

### DETAILED DESCRIPTION

FIG. 1 shows an external view of a differential current measuring module 2 according to the invention that is mounted on a printed mounting board 3. The differential current measuring module 2 is an integrated component for differential current measurement with which the printed mounting board 3 can be equipped.

In the illustrated embodiment example, the differential current measuring module 2 is composed of a split housing 4 having an upper housing part 4a and a lower housing part 4b. The housing 4 has a cylindrical line duct 6 in which four primary conductors 8 are arranged as part of the differential current measuring module 2.

The four primary conductors 8 thus form line sections by which an electrical feed line to be monitored having three phase conductors (L1, L2, L3) and a neutral conductor (N) is continued in the line duct 6 for registering a differential current.

Additionally, in single-phase or two-phase power supply systems with high current loads, the illustrated four-pole design allows an increase of the primary current range to twice the value by the parallel connection of pairs of the primary conductors 8.

At a top side 10a of the housing 4, the primary conductors 8 are led outside at right angles in a crosswise arrangement and are fixed to the top side 10a of the housing 4 by means of clamping devices 12. Said clamping devices 12 are realized as snap elements.

In the line duct 6, a separating web 14 running parallel to the line duct 6 is arranged for keeping the distances of the primary conductors 8. The separating web 14 is composed of four web walls 16 that are arranged in the shape of a cross so that the line duct 6 is divided into four separate conductor channels in each of which one primary conductor 8 is led in an isolated manner.

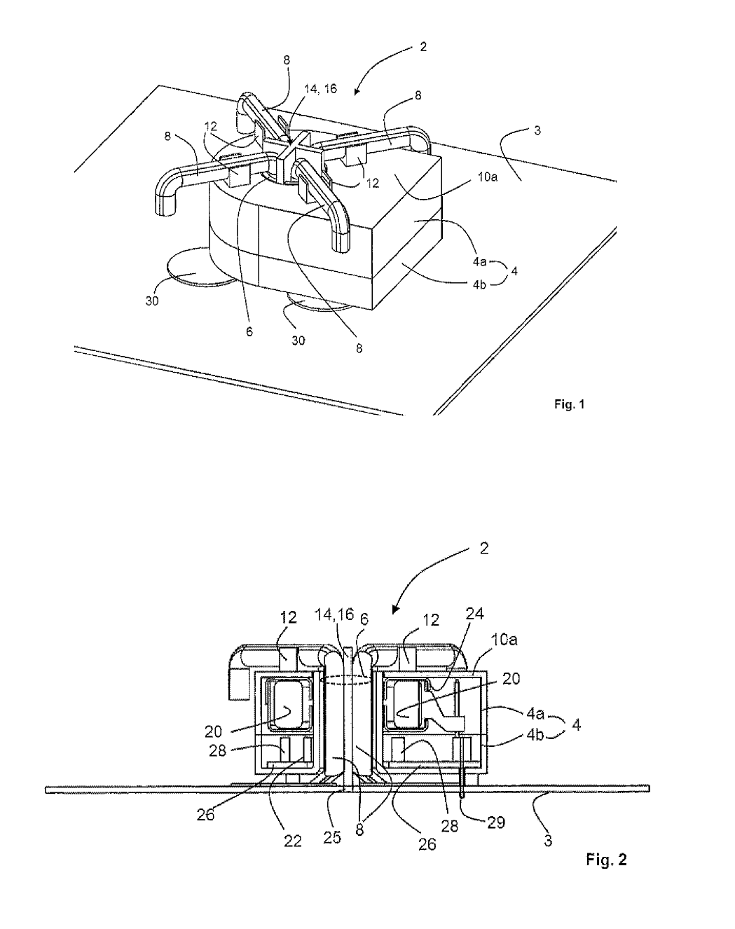

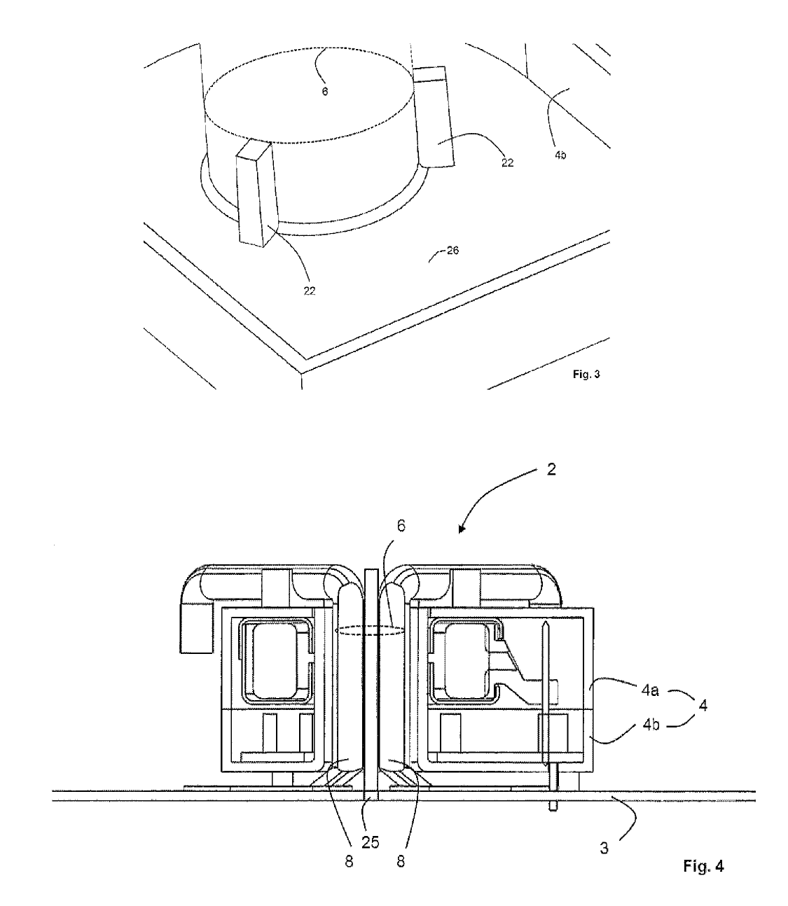

In FIG. 2, an interior structure of the differential current measuring module 2 is illustrated in a cross-section. The current transformer core 20 enclosed by a shielded transformer housing 24 is visible in the upper housing part 4a. The current transformer core 20 is mounted on supporting pads 22. FIG. 3 shows a detailed vie of the supporting pads 22.

As FIG. 2 further shows, the web walls 16 of the separating web 14 protrude beyond a bottom side 10b of the housing 4 and enter a slot 25 of the printed mounting board 3.

The installation space remaining below the current transformer core 20 between the housing bottom and the current transformer core 20 is used to arrange a printed circuit board 26 with electronic components 28 within the housing 4. The printed circuit board 26 has a cutout in the shape of the cross-section of the line duct 6 so that the line duct is annularly enclosed by the printed circuit board 26. The printed circuit board 26 is equipped with electronic components 28 that form an evaluating circuit for processing a measuring signal provided by a secondary winding (not illustrated) of the current transformer core 20.

Pin contacts 29 arranged at the bottom side of the housing 4 produce a contact to the printed mounting board 3.

This arrangement as well as mounting the evaluating circuit on a flexible printed circuit board allows a compact and place-saving design of the differential current measuring module 2.

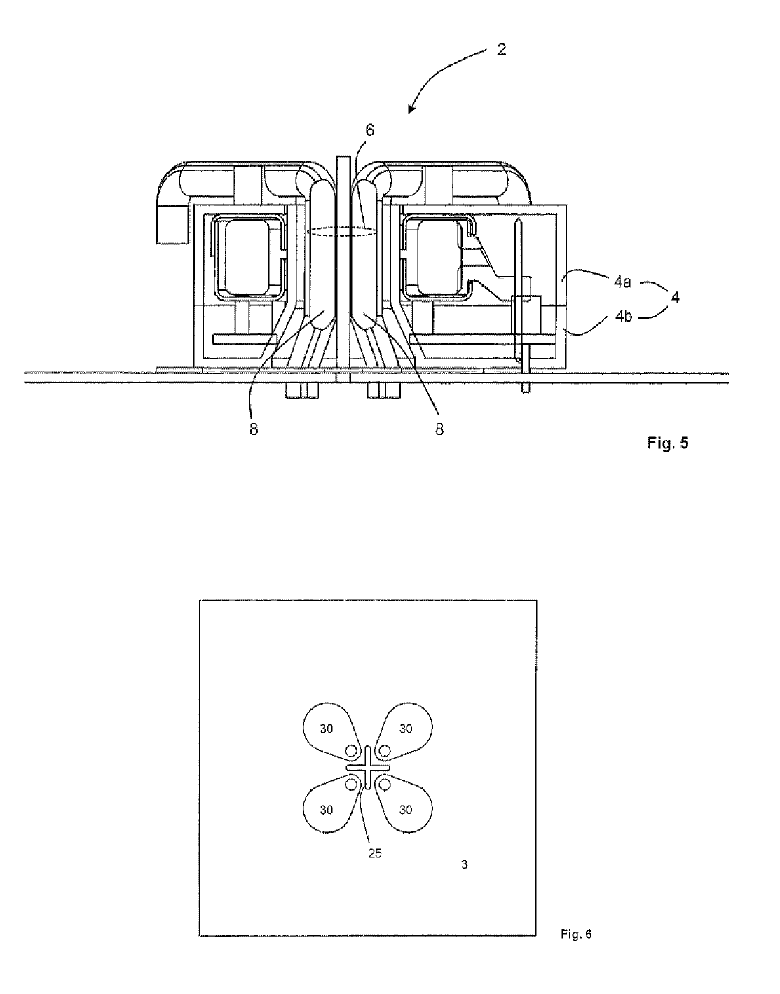

FIG. 4 and FIG. 5 illustrate a version of the differential current measuring module 2 having a cylindrical line duct 6 and a constant diameter (FIG. 4) and a version of the differential current measuring module 2 having a cylindrical line duct 6 and a conical expansion (FIG. 5). In the case of the conical expansion of the line duct 6, the inner diameter of the lower housing part 4b at the lower exit of the line duct 6 is enlarged compared to the lower housing part 4b of FIG. 4 having a constant diameter so that the primary conductors 8 can be led in a radially bent manner at larger distances to one another onto the printed mounting board 3. This allows an advantageous enlargement of the clearances and creepage distances in comparison to the design having a constant diameter so that a separating web 14 protruding into the printed mounting board 3 and a slot 25 of the printed mounting board 3 are unnecessary.

FIG. 6 shows a printed mounting board 3 having a slot 25 for a cruciform separating web 14 and having solder pads 30 for soldering the primary conductors 8. The solder pads 30 have the shape of drops so as to optimize the clearances and creepage distances and for maximizing the conductor cross-section in the area of the passage of the primary conductors 8 onto the printed mounting board 3. The slot 25 of the printed mounting board 3 also leads to an enlargement of the creepage distances.

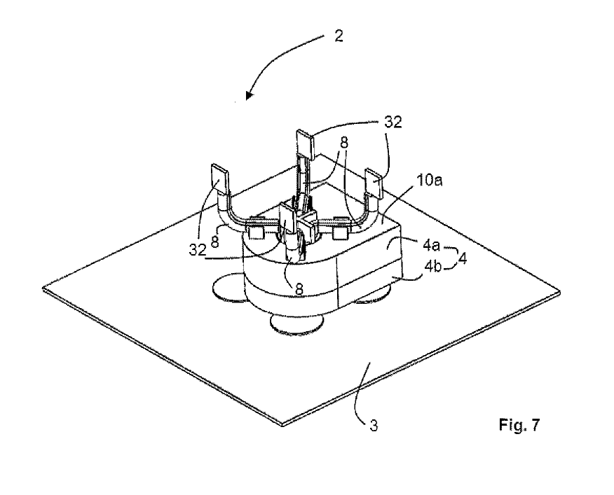

In FIG. 7, the differential current measuring module 2 is illustrated with primary conductors 8 that are provided with a plug contact 32 at each of their ends that are led out at the top side 10a of the housing 4. By means of the plug contacts 32, a detachable electrical connection to the feed line to be monitored can be produced in a simple fashion.

1. A differential current measuring module (2) composed of a housing (4) that encases a current transformer core (20) and a printed circuit board (26), the current transformer core (20) surrounding a line duct (6) of the housing (4) and having at least one secondary winding, characterized in that
in the line duct (6), at least one primary conductor (8) is arranged that is led out on a top side (10a) of the housing (4) so as to be connected to an external electrical feed line and whose other end protrudes out of a bottom side (10b) of the housing and is provided with a solder terminal.

2. The differential current measuring module (2) according to claim 1, characterized in that
a separating web (14) that runs parallel to the line duct (6) is arranged in the line duct (6) to keep the distances of the primary conductor (8).

3. The differential current measuring module (2) according to claim 2, characterized in that
the separating web (14) arranged in the line duct (6) consists of four web walls (16) that are arranged in the shape of a cross so that the line duct (6) is divided into four separate conductor channels in each of which a primary conductor (8) is led in an isolated manner.

4. The differential current measuring module (2) according to claim 2, characterized in that
the separating web (14) protrudes beyond the top side (10a) of the housing (4) so that the primary conductor (8) can be continued in the outward direction in an isolated manner above the housing (4).

5. The differential current measuring module (2) according to claim 2, characterized in that
the separating web (14) protrudes beyond the bottom side (10b) of the housing (4).

6. The differential current measuring module (2) according to claim 2, characterized in that
the separating web (14) is realized as a separate component that can be inserted into and removed from the line duct (6) of the housing.

7. The differential current measuring module (2) according claim 1, characterized in that
clamping devices (12) for securing the primary conductor (8) that is led out of the line duct (6) in a rectangular fashion are attached to the top side (10a) of the housing (4).

8. The differential current measuring module (2) according to claim 1, characterized in that
the line duct (6) of the housing (4) has a conical expansion at the bottom side (10b) of the housing (4) so that the primary conductors (8) can be positioned at larger distances while being bent radially outward.

9. The differential current measuring module (2) according to claim 1, characterized in that
the housing (4) has an upper housing part (4a) and a lower housing part (4b) which can be connected to each other by means of a latching connection.

10. The differential current measuring module (2) according to claim 1, characterized in that
the housing (4) is a housing that is cast in one piece.

11. The differential current measuring module (2) according to claim 1, characterized in that
the current transformer core (20) is mounted on supporting pads (22) for internal positioning in the housing.

12. The differential current measuring module (2) according to claim 1, characterized in that
output signals that are generated by an evaluating circuit arranged on the printed circuit board (26) are led out at the bottom side of the housing (4) via pin contacts (29).

13. The differential current measuring module (2) according to claim 1, characterized in that
the primary conductor (8) is provided with a plug contact (32) at its end led out at the top side (10a) of the housing (4).

14. The differential current measuring module (2) according to claim 13, characterized in that
the primary conductor (8) provided with the plug contact (32) is realized as a separate constructional unit that can be inserted into and removed from the line duct (6) of the housing (4).

15. The differential current measuring module (2) according to claim 14, characterized by
a plug housing through which the plug contacts (32) of the primary conductors (8) can protrude and be contacted with a mating plug.
